(19) United States
(12) Patent Application Publication
(10) Pub. No.: US 2012/0094011 A1
(43) Pub. Date: Apr. 19, 2012

(54) FILM DEPOSITION APPARATUS AND FILM DEPOSITION METHOD

(75) Inventors: Katsuyuki HISHIYA, Iwate (JP); Manabu Honma, Iwate (JP); Tsuneyuki Okabe, Iwate (JP)

(73) Assignee: Tokyo Electron Limited

(21) Appl. No.: 13/270,288

(22) Filed: Oct. 11, 2011

(30) Foreign Application Priority Data
Oct. 15, 2010 (JP) NO. 2010-232499

(51) Int. Cl. C23C 16/52

(52) U.S. Cl. 427/8; 118/663

(57) ABSTRACT

A film deposition apparatus includes a partitioning member that forms, in a chamber, a film deposition space including a turntable on which a substrate is placed, a first reactive gas supplying portion for supplying a first reactive gas toward the turntable, and a second reactive gas supplying portion for supplying a second reactive gas toward the turntable. The partitioning member is fabricated with material superior to material forming the chamber in corrosion resistance. The film deposition apparatus includes a pressure measurement portion that measures a pressure of the film deposition space, and a pressure measurement portion that measures a pressure of a space outside the film deposition space, so that the pressure of the space outside the film deposition space is kept slightly higher than the pressure of the film deposition space based on the pressure measurements.

### CROSS-REFERENCE TO RELATED APPLICATION

The present application is based upon and claims the benefit of priority of Japanese patent application No. 2010-232499, filed on Oct. 15, 2010, the entire contents of which are incorporated by reference in their entirety.

### BACKGROUND OF THE PRESENT DISCLOSURE

1. Field of the Present Disclosure

The present disclosure relates to a film deposition apparatus and a film deposition method which are adapted to deposit a film on a substrate in a chamber by performing a number of cycles of sequentially supplying at least two kinds of mutually reactive gases to the substrate to laminate layers of resultants of the reactive gases on the substrate.

2. Description of the Related Art

As one of fabrication processes of semiconductor integrated circuits (ICs), there is a film deposition method called Atomic Layer Deposition (ALD) or Molecular Layer Deposition (MLD). This film deposition method may be carried out in a turntable type ALD apparatus. An example of such an ALD apparatus has been proposed by the applicant of this patent application. See Patent Document 1 listed below.

The ALD apparatus of Patent Document 1 is provided with a turntable that is arranged in a vacuum chamber and on which, for example, five substrates are placed, a first reactive gas supplying part that supplies a first reactive gas toward the substrates on the turntable, a second reactive gas supplying part that supplies a second reactive gas toward the substrates on the turntable and is arranged away from the first reactive gas supplying part in the vacuum chamber. In addition, the vacuum chamber includes a separation area that separates a first process area in which the first reactive gas is supplied from the first reactive gas supplying part and a second process area in which the second reactive gas is supplied from the second reactive gas supplying part. The separation area includes a separation gas supplying part that supplies a separation gas and a ceiling surface that creates a thin space with respect to the turntable thereby to maintain the separation area at a higher pressure than the pressures in the first and the second process areas with the separation gas from the separation gas supplying part.

With such a configuration, because the first and the second process areas are separated by the separation area that is kept at a sufficiently high pressure, the first reactive gas and the second reactive gas can be impeded from being intermixed in the vacuum chamber, even when the turntable is rotated at a high rotational speed, thereby improving production throughput.

On the turntable of the above-mentioned ALD apparatus, five substrates of a diameter of 300 mm or 450 mm, for example, are placed. Thus, the size of the ALD apparatus becomes relatively large. Therefore, the ALD apparatus is manufactured with aluminum and the like instead of stainless steel having a large specific gravity. In the case when the ALD apparatus is manufactured by aluminum and the like, depending on reactive gases to be used, a possibility in that the inner surface of the vacuum chamber may be corroded is higher than the stainless steel. It can be considered to cover the inner surface of the vacuum chamber made of aluminum with an inner member fabricated with material such as quartz having high corrosion resistance in order to prevent corrosion.

However, since it is hard to fix the inner member made of quartz to the vacuum chamber by using a screw and the like, the inner member is merely placed in the vacuum chamber. In this case, if large pressure variation occurs in the vacuum chamber, the inner member is displaced, so that a problem may occur in that the inner surface of the vacuum chamber made of aluminum is exposed to a corrosive gas and the inner member is broken so that particles are released.

Patent Document 1: Japanese Laid-Open Patent Publication No. 2010-56470

### SUMMARY OF THE PRESENT DISCLOSURE

The present invention has been made in view of the above circumstances, and is directed to an atomic layer (molecular layer) film deposition apparatus that can reduce displacement or break of the inner member that is fabricated with material having high corrosion resistance and that is placed in the vacuum chamber.

A first aspect of the present invention provides a film deposition apparatus that supplies at least two kinds of mutually reactive gases sequentially to a substrate disposed in a chamber and laminates layers of resultants of the reactive gases on the substrate to deposit a film thereon. The film deposition apparatus includes:

a turntable that is rotatably arranged in the chamber and includes a substrate receiving area in which the substrate is placed;

a first reactive gas supplying portion that extends in a direction intersecting with a rotation direction of the turntable, and that supplies a first reactive gas toward the turntable;

a second reactive gas supplying portion that is separated from the first reactive gas supplying portion along the rotation direction of the turntable, that extends in a direction intersecting with the rotation direction of the turntable, and that supplies a second reactive gas toward the turntable;

a partitioning member that forms, in the chamber, a film deposition space including the turntable, the first reactive gas supplying portion, and the second reactive gas supplying portion, and that is fabricated with material superior to material forming the chamber in corrosion resistance;

an exhaust portion that exhausts gas from the film deposition space formed by the partitioning member;

a first purge gas supplying portion that supplies a purge gas to an outside space outside the film deposition space in the chamber;

a first pressure measurement portion that measures a pressure of the film deposition space and a pressure of the outside space;

a first tube that communicates the outside space with the exhaust portion via a first open and close valve;

a control portion that compares the pressure of the film deposition space with the pressure of the outside space so as to control the first open and close valve according to a result of the comparison;

a separation gas supplying portion that is located between the first reactive gas supplying portion and the second reactive gas supplying portion along the rotation direction and that supplies a separation gas; and

a ceiling surface that forms, for the turntable, a separation space that is located in both sides of the separation gas supplying portion for introducing the separation gas to a first area including the first reactive gas supplying portion and a second area including the second reactive gas supplying portion, and that is arranged such that the pressure of the separation space can be set to be higher than a pressure of the first area and the second area.

A second aspect of the present invention provides a film deposition method performed in a film deposition apparatus that supplies at least two kinds of mutually reactive gases sequentially to a substrate disposed in a chamber and laminates layers of resultants of the reactive gases on the substrate to deposit a film thereon. The film deposition method includes the steps of:

placing a substrate on a turntable that is rotatably arranged in the chamber;

supplying a first reactive gas toward the turntable from a first reactive gas supplying portion that extends in a direction intersecting with a rotation direction of the turntable;

supplying a second reactive gas toward the turntable from a second reactive gas supplying portion that is separated from the first reactive gas supplying portion along the rotation direction of the turntable, and that extends in a direction intersecting with the rotation direction of the turntable;

exhausting gas from a film deposition space that is formed by a partitioning member fabricated with material superior to material forming the chamber in corrosion resistance, and that includes the turntable, the first reactive gas supplying portion, and the second reactive gas supplying portion;

supplying a purge gas to an outside space outside the film deposition space in the chamber;

measuring a pressure of the film deposition space and a pressure of the outside space;

comparing the pressure of the film deposition space with the pressure of the outside space so as to control a first open and close valve that is provided in a first tube used for communicating the outside space with an exhaust portion; and

supplying a separation gas from a separation gas supplying portion that is located between the first reactive gas supplying portion and the second reactive gas supplying portion along the rotation direction in the film deposition space so as to set a pressure of a separation space formed by a ceiling surface arranged in both sides of the separation gas supplying portion to be higher than a pressure of a first area including the first reactive gas supplying portion and a second area including the second reactive gas supplying portion.

Other objects, features and advantages of the present invention will become more apparent from the following detailed description when read in conjunction with the accompanying drawings.

### BRIEF DESCRIPTION OF THE DRAWINGS

FIG. 1 is a plan view of a film deposition apparatus according to an embodiment of the present invention;

FIG. 2 is a cross-sectional diagram of the film deposition apparatus according to an embodiment of the present invention, taken along a line I-I indicated in FIG. 1;

FIG. 3 is a perspective diagram illustrating the film deposition apparatus according to an embodiment of the present invention;

FIG. 4 is another perspective diagram illustrating the film deposition apparatus according to an embodiment of the present invention;

FIGS. 5A-5C are explanatory diagrams for explaining an upper plate, a separation member and a side ring arranged in the inside of the film deposition apparatus according to an embodiment of the present invention;

FIG. 6 is an explanatory diagram for explaining an effect exhibited by a separation area in the film deposition apparatus according to an embodiment of the present invention;

FIG. 7 is a cross-sectional diagram showing a section of the film deposition apparatus according to an embodiment of the present invention, taken along a line I-II indicated in FIG. 1; and

FIG. 8 is another cross-sectional diagram showing a section of the film deposition apparatus according to an embodiment of the present invention, taken along a line I-II indicated in FIG. 1.

### DETAILED DESCRIPTION OF PREFERRED EMBODIMENTS

A description will now be given of non-limiting, exemplary embodiments of the present disclosure with reference to the accompanying drawings. In the drawings, the same or corresponding reference numerals or letters are given to the same or corresponding members or components. It is noted that the drawings are illustrative of the present disclosure, and there is no intention to indicate scale or relative proportions among the members or components. Therefore, the specific size should be determined by a person having ordinary skill in the art in view of the following non-limiting embodiments.

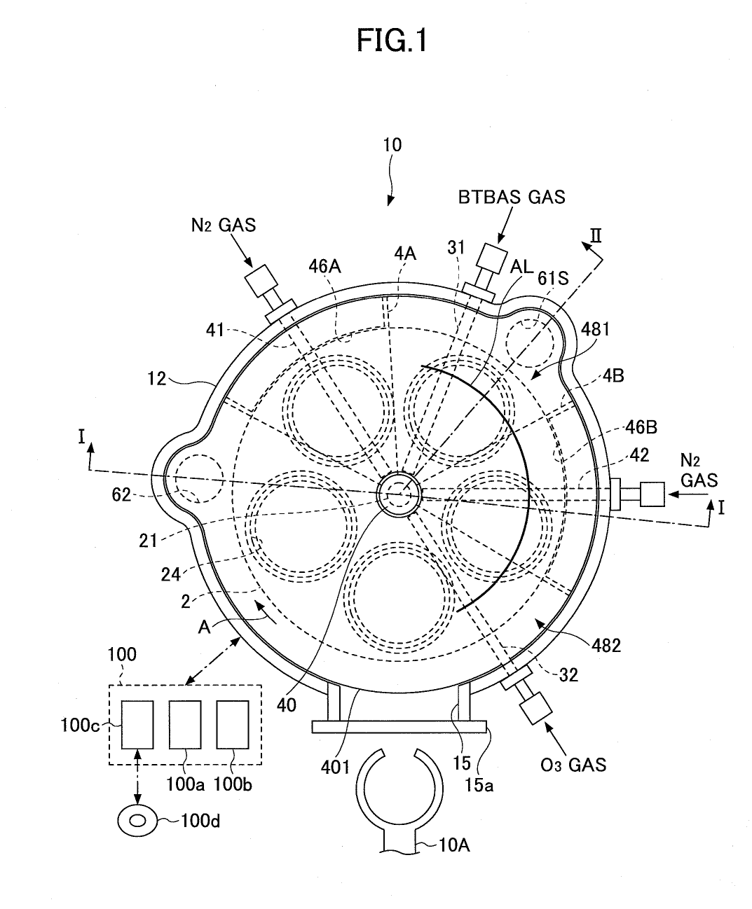

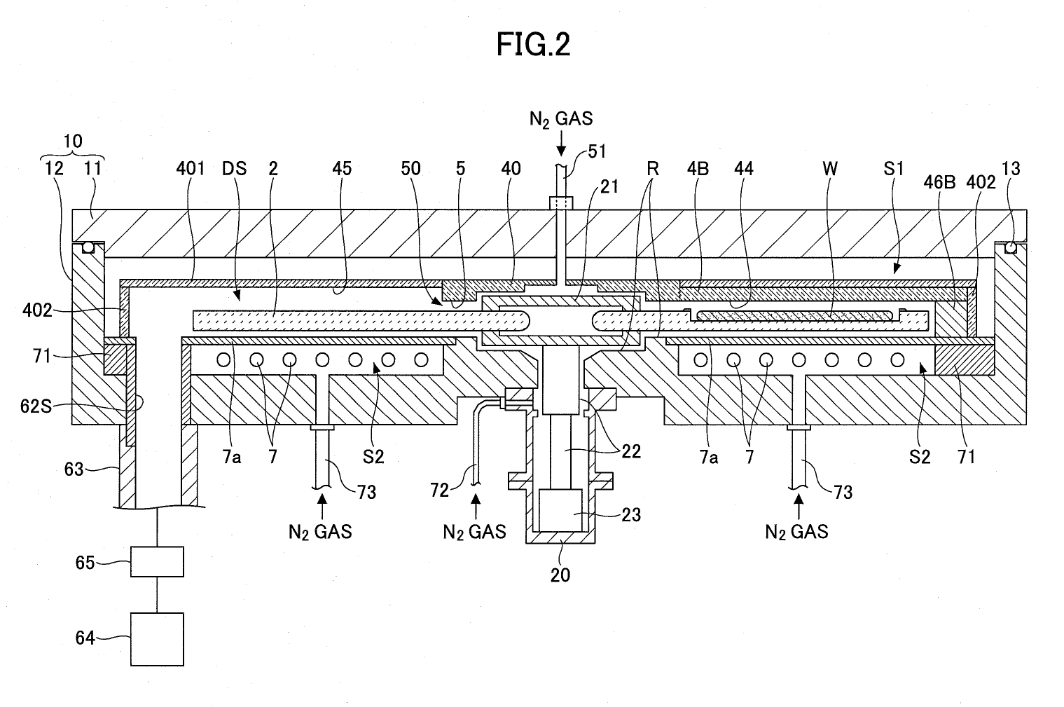

As shown in FIGS. 1 and 2, a film deposition apparatus according to an embodiment of the present invention is provided with a vacuum chamber 10 having a flattened cylinder shape, and a turntable 2 that is located inside the vacuum chamber 10 and has a rotation center at a center of the vacuum chamber 10.

As shown in FIG. 2, which is a cross-sectional view taken along an I-I line of FIG. 1, the vacuum chamber 10 includes a chamber body 12 having a shape of a flattened cylinder with a bottom, and a ceiling plate 11 that is placed on the chamber body 12 via a ceiling member 13 such as an O ring in an airtight manner. As shown in FIG. 1, a transfer opening 15 is formed in the circumferential wall of the chamber body 12. A wafer W is transferred into or out from the vacuum chamber 10 through the transfer opening 15. The transfer opening 15 is provided with a gate valve 15a that opens or closes the transfer opening 15. The ceiling plate 11 and the chamber body 12 are made of metal such as aluminum (Al).

Referring to FIG. 1, plural circular substrate receiving areas 24, each of which receives a wafer W, are formed in an upper surface of the turntable 2. In the present embodiment, each of the substrate receiving areas 24 is configured as a concave portion having a diameter slightly larger, for example, by 4 mm than the diameter of the wafer W and having a depth almost equal to a thickness of the wafer W, such that a wafer having a diameter of 300 mm can be placed. Since the substrate receiving area 24 is configured like this, when the wafer W is placed in the receiving area 24, a surface of the wafer W is at the same elevation of a surface of an area of the turntable 2, the area excluding the substrate receiving areas 24. Because there is substantially no step between the upper surface of the wafer W and the upper surface of the turntable 2, gas flow turbulence can be reduced on the turntable 2. In addition, because the wafer W is accommodated within the receiving area 24, the wafer W is not thrown out and the wafer W can stay in the receiving area 24 even when the turntable 2 is rotated.

As shown in FIG. 2, the turntable 2 has a circular opening at the center thereof, and the portion of the turntable 2 around the opening is sandwiched between the upper and lower sides of a cylinder-shaped core portion 21 and firmly held. The lower part of the core portion 21 is fixed to a rotary shaft 22, and the rotary shaft 22 is connected to a driving device 23. The core portion 21 and the rotary shaft 22 have a common axis of rotation, and, the rotary shaft 21, the core portion 21 and the turntable 2 can be rotated by the rotation of the driving device 23.

The rotary shaft 22 and the driving device 23 are housed in a cylindrical case body 20 having an open top surface. The case body 20 is attached to the back surface of the bottom of the vacuum chamber 10 via a flange portion 20a provided in the top surface of the case body 20 in an airtight manner, so that an internal atmosphere of the case body 20 is isolated from an external atmosphere.

As shown in FIG. 2, a heater unit space S2 is formed in a lower part of the turntable 2. The heater unit space S2 is defined by a raised part R formed around the center of the chamber body 12, a lower block member 71 provided along the inner periphery of the chamber body 12, and an annular lower plate 7a made of quartz, for example, that is held by the raised part R and the lower block member 71. The heater unit space S2 is provided with a heater unit 7. By the heater unit 7, the wafer W on the turntable 2 is heated to a predetermined temperature via the turntable 2. Also, the heater unit 7 may include plural lump heaters placed in a concentric fashion, for example. By controlling each lump heater independently, the temperature of the turntable 2 can be made even.

At the bottom part of the chamber body 12, plural purge gas supplying tubes 73 are connected at predetermined intervals such that the purge gas supplying tubes 73 penetrate through the bottom part of the chamber body 12. Accordingly, a nitrogen gas, for example, is supplied to the heater unit space S2.

Also, as shown in FIG. 1, a part of the side wall of the chamber body 12 projects outward. In the area where the side wall projects, a through-hole that penetrates through the bottom part of the chamber body 12 is formed, and an exhaust sleeve 62S is fitted into the through-hole. Another part of the side wall of the chamber body 12 projects outward. In the area where the side wall projects, a through-hole that penetrates through the bottom part of the chamber body 12 is formed, and an exhaust sleeve 61S is fitted into the through-hole. It is preferable that the exhaust sleeves 61S and 62S are fabricated with material superior in corrosion resistance such as quartz, for example. Also, in the present embodiment, the exhaust sleeves 61S and 62S are connected separately to an exhaust device 64 including a pressure regulator 65 and a turbo molecular pump and the like, for example, via an exhaust tube 63. Accordingly, the pressure in the vacuum chamber 10 is adjusted. That is, the exhaust sleeves 61S and 62S form exhaust ports for the vacuum chamber 10.

Openings corresponding to the exhaust sleeves 61S and 62S are formed in the above-mentioned lower plate 7a. Therefore, gas exhaust from the vacuum chamber 10 is not prevented by the lower plate 7a.

As shown in FIG. 2, a side ring 402 is placed on the lower plate 7a. An upper plate 401 is placed on the side ring 402. The upper plate 401 has its opening above the core part 21, and a center circular portion 5 of an after-mentioned separation member 40 is inserted into the opening. According to such a configuration, the inside of the vacuum chamber 10 is partitioned into a film deposition space DS and an outside space S1. The film deposition space DS is a space surrounded by the lower plate 7a, the side ring 402 and the upper plate 401. Also, after-mentioned reactive gas nozzles 31 and 32, the separation member 40, separation gas nozzles 41 and 42, and the turntable 2 are arranged in the inside of the film deposition space DS. The outside space S1 is a space surrounded by the side ring 402, the upper plate 401, the chamber body 12 and the ceiling plate 11. Also, the vacuum chamber 10 is provided with the above-mentioned heater unit space S2. The lower plate 7a, the side ring 402 and the upper plate 401 are fabricated with material (quartz in the present embodiment) having high corrosion resistance and high heat resistance.

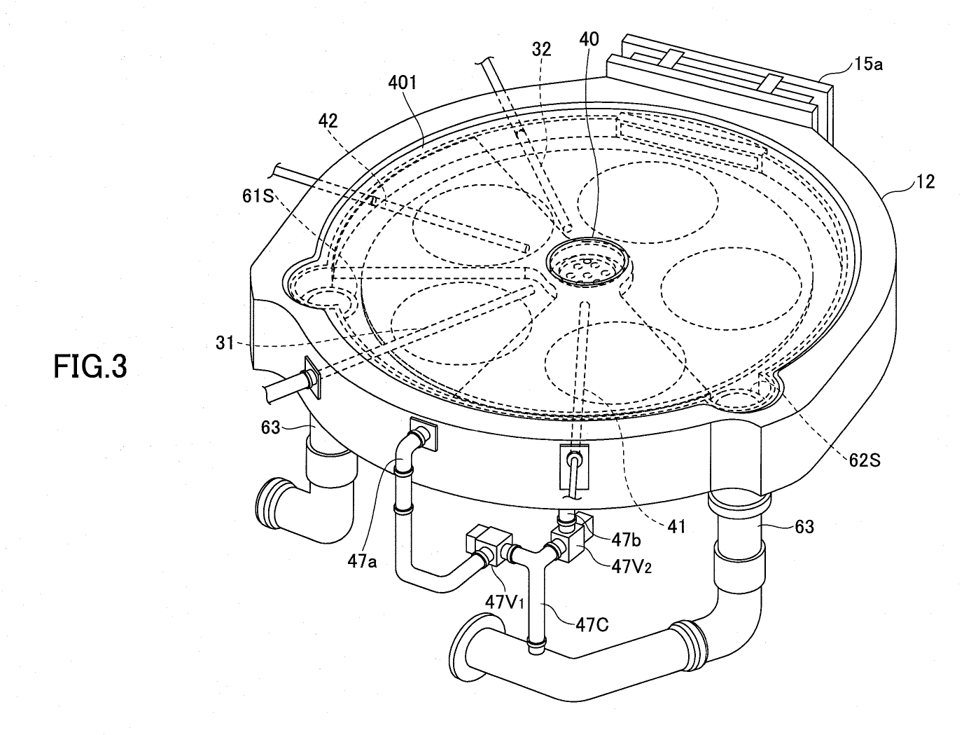

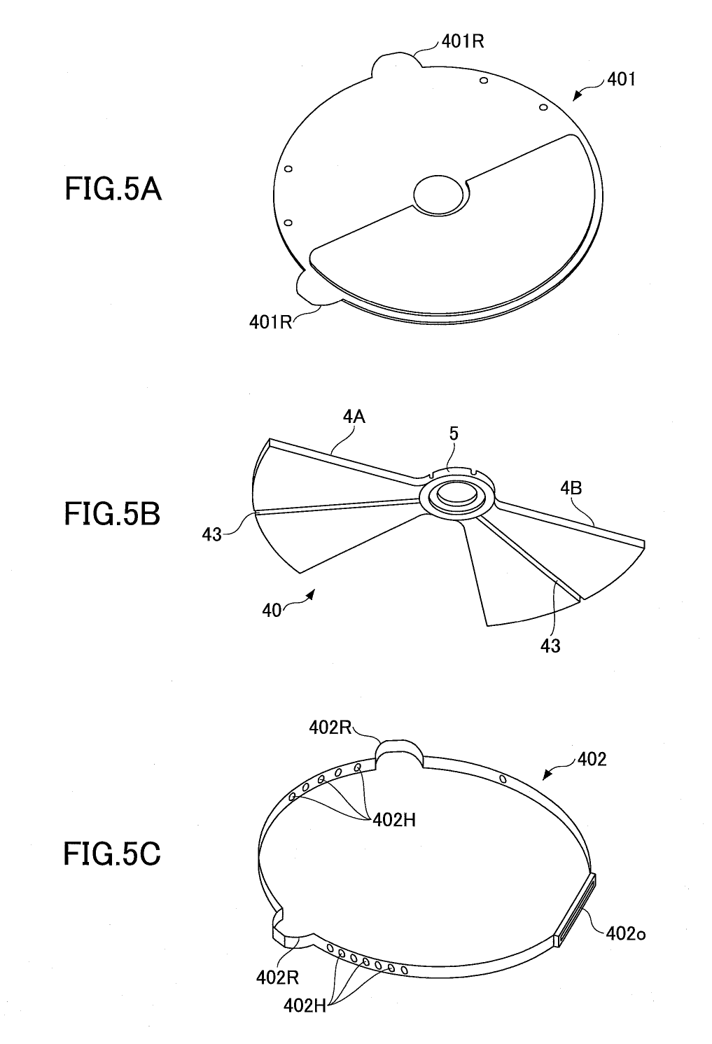

Next, the upper plate 401, the separation member 40 and the side ring 402 are described in detail with reference to FIGS. 3-5. FIG. 3 is a perspective view showing the vacuum chamber 10. For the sake of convenience of explanation, FIG. 3 shows a state in which the ceiling plate 11 is removed. As shown in the figure, the upper plate 401 is positioned lower than the upper surface of the side wall of the chamber body 12 in the inside of the chamber body 12. The shape of the upper surface of the upper plate 401 is almost round, and the diameter is greater than the diameter of the turntable 2 in the chamber body 12 and smaller than the internal diameter of the chamber body 12. Therefore, there is a small gap between the upper plate 401 and the inner periphery of the chamber body 12. Also, as shown in FIG. 5A, two tongue-like portions 401R are formed on the outer periphery of the upper plate 401. These tongue-like portions 401R cover upper parts of areas where the exhaust sleeves 61S and 62S are arranged.

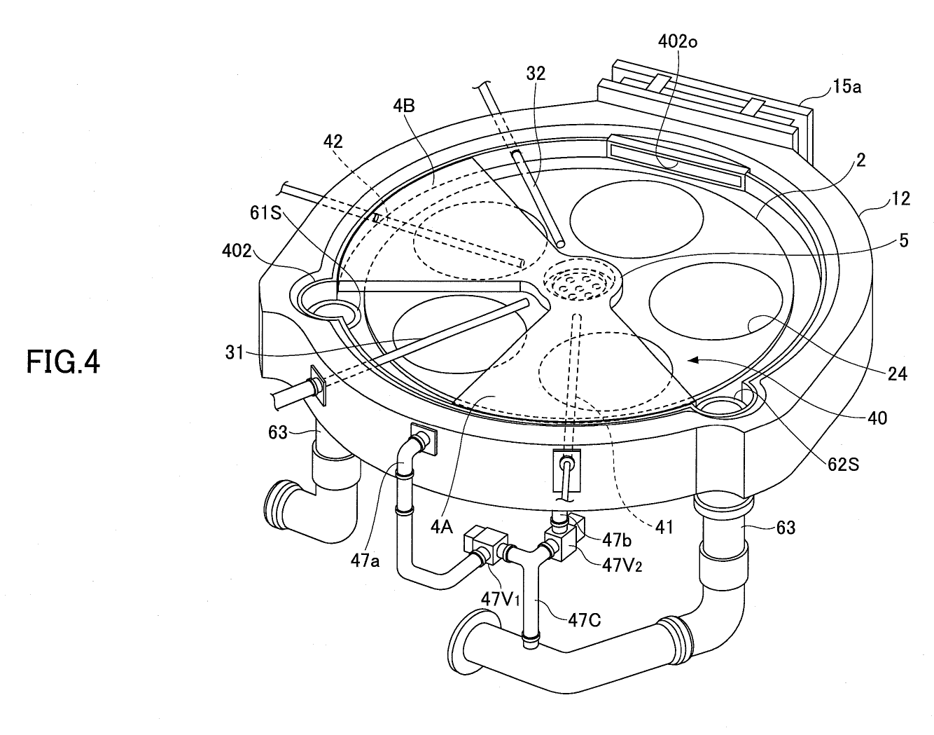

FIG. 4 shows another perspective view showing the vacuum chamber 10, and shows a state in which the ceiling plate 11 and the upper plate 401 are removed. As shown in the figure, the separation member 40 includes a center circular portion 5 having an upper surface of an approximately-circular shape, and includes sector portions 4A and 4B connected to the center circular portion 5. The center circular portion 5 is positioned at an upper part of the core portion 21 (refer to FIG. 2) that fixes the turntable 2. Each of the sector portions 4A and 4B has an upper surface of an approximately-sector shape in which the width becomes wider along a direction from the center circular portion 5 toward the inner periphery of the chamber body 12. As shown in FIG. 5B, each of the sector portions 4A and 4B includes a slot 43 in a side (lower side) opposite to the turntable 2 in the vacuum chamber 10. After-mentioned separation gas nozzles 41 and 42 are accommodated in the slots 43. Also, as shown in FIG. 2, the lower part of the center circular portion 5 is depressed along the outer shape of the core portion 21, and the center circular portion 5 suits to the core portion 21 as described later. In addition, the center part of the center circular portion 5 is provided with a through-hole. The through-hole is provided for the separation gas supply tube 51 that penetrates through the ceiling plate 11 as shown in FIG. 2.

The center circular portion 5 of the separation member 40 protrudes from the upper side surface of the sector portions 4A and 4B, and fits into the opening of the center part of the upper plate 401. On the other hand, the sector portions 4A and 4B contact the lower surface of the upper plate 401 (refer to the sector portion 4B of FIG. 2). But, the sector portions 4A and 4B are separated from the turntable 2. Thus, rotation of the turntable 2 is not hindered by the sector portions 4A and 4B. Since the sector portions 4A and 4B are placed such that they contact the lower surface of the upper plate 401, a lower ceiling surface 44 is formed in areas where the sector portions 4A and 4B are provided, and a higher ceiling surface 45 is formed in areas where the sector portions 4A and 4B are not provided for the turntable 2 (refer to FIG. 2). The ceiling surface 45 corresponds to a lower surface of the upper plate 401.

The separation member 40 is held by a holding rod (not shown in the figure) provided in the lower plate 7a. A concave portion into which the separation member 40 can be fit may be formed in the lower surface side of the upper plate 401 in order to position the separation member 40 and the upper plate 401 that is placed on the side ring 402.

As shown in FIG. 5C, when viewed from above, the side ring 402 has almost a ring shape. The outside diameter of the side ring 402 is the same as or slightly smaller than the outside diameter of the upper plate 401. Accordingly, the side ring 402 can hold the upper plate 401. Also, since the tongue-like portions 401R are provided on the upper plate 401 for the areas where the side wall projects outward, two curved portions 402R, corresponding to the tongue-like portions 401R, projecting outward are formed in the side ring 402. In addition, an opening 402o corresponding to the transfer opening 15 formed on the side wall of the chamber body 12 is formed in the side ring 402. Also, the side ring 402 includes openings 402H though which after-mentioned reactive gas nozzles 31 and 32, and separation gas nozzles 41 and 42 penetrate.

Referring to FIG. 4 again, the chamber body 12 is provided with the separation gas nozzle 41, the reactive gas nozzle 31, the separation gas nozzle 42 and the reactive gas nozzle 32 that penetrate through the side wall, and that are attached in an airproof manner to the chamber body 12 by a joint member. These nozzles 31, 32, 41 and 42 are arranged in this order in clockwise direction when viewed from above, and extend along the radius direction of the vacuum chamber 10 being nearly parallel to the upper surface of the turntable 2. In these nozzles, the separation gas nozzles 41 and 42 are accommodated in the slots 43 (refer to FIG. 5B) formed on the sector portions 4A and 4B of the separation member 40 respectively, and the reactive gas nozzles 31 and 32 are provided in areas where the sector portions 4A and 4B of the separation member 40 are not provided in the chamber body 12. More particularly, the reactive gas nozzle 31 is placed in an upstream side of the rotation direction of the turntable 2 with respect to the exhaust sleeve 61S forming an exhaust port, and the reactive gas nozzle 32 is placed in an upstream side of the rotation direction of the turntable 2 with respect to the exhaust sleeve 62S foaming an exhaust port. More particularly, as shown in FIG. 1, the reactive gas nozzle 31, the exhaust sleeve 61S and the sector portion 4B are placed in this order along the rotation direction A of the turntable 2, and the reactive gas nozzle 32, the exhaust sleeve 62S and the sector portion 4A are placed in this order along the rotation direction A of the turntable 2. For the sake of convenience of explanation, an area where the reactive gas nozzle 31 is provided is referred to as a first area 481, and an area where the reactive gas nozzle 32 is provided is referred to as a second area 482.

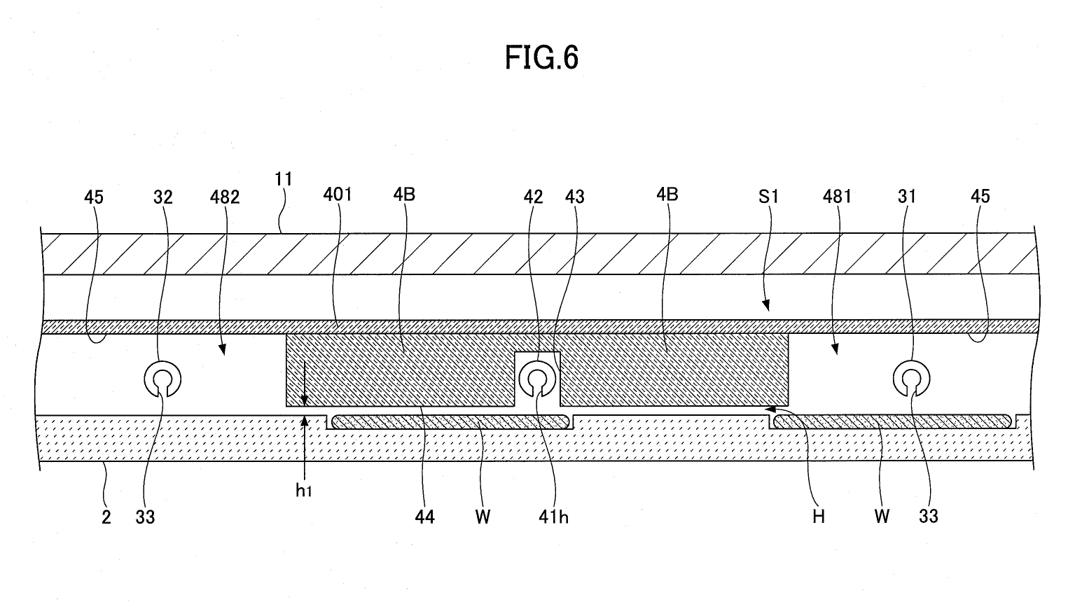

Also, each of the separation gas nozzles 41 and 42 includes discharge holes (reference symbol 41h in FIG. 6) for discharging a separation gas to the surface of the turntable 2. In the present embodiment, the discharge hole 41h has a diameter of about 0.5 mm. The discharge holes are arranged at intervals of about 10 mm in the length direction of the separation gas nozzle 41 (42). Also, each of the reactive gas nozzles 31 and 32 is provided with plural discharge holes (reference symbol 33 of FIG. 6), each having a diameter of about 0.5 mm and opening downward, that are arranged at intervals of about 10 mm along the length direction of the nozzle.

The separation gas nozzles 41 and 42 are connected to a separation gas supplying source (not shown in the figure) for supplying the separation gas. The separation gas may be a nitrogen (N₂) gas or an inert gas. The separation gas is not limited to a particular gas as long as the gas does not affect film deposition. In the present embodiment, the N₂ gas is used as the separation gas. Also, in the present embodiment, the reactive gas nozzle 31 is connected to a gas supplying source of bis (tertiary-butylamino) silane (BTBAS) that is silicon raw material of a silicon oxide film, and the reactive gas nozzle 32 is connected to a gas supplying source of O₃ (ozone) gas as an oxidization gas for generating the silicon oxide by oxidizing BTBAS.

Next, a function of the separation member 40 is described with reference to FIG. 6 that is a section view along the additional line AL shown in FIG. 1.

As shown in FIG. 6, a separation space H having a height h1 (height from the surface of the turntable 2 to the lower surface 44 of the sector portion 4B) is formed by the separation table 2 and the sector portion 4B. The height h1 is preferably in a range of 0.5 mm-10 mm, and also it is more preferable to decrease the height h1 as much as possible. But, in order to prevent the turntable 2 from colliding with the ceiling surface 44 due to rotation deflection of the turntable 2, it is preferable that the high hl is in a range of about 3.5 mm-6.5 mm. On the other hand, as mentioned above, there is an area defined by a high ceiling surface (lower surface of the upper plate 401) 45 in both sides of the sector portion 4B. The height of the ceiling surface 45 (height from the turntable 2 to the upper plate 401) is 15 mm-150 mm, for example.

The reactive gas nozzles 31 and 32 are provided being separated from the turntable 2 and also from the lower surface of the ceiling plate 11 (ceiling surface 45). The distance between the reactive gas nozzle 31, 32 and the surface of the turntable 2 may be between 0.5 mm and 4 mm. Also, considering the rotation deflection of the turntable 2, the distance may be set to be between 3.5 mm and 6.5 mm.

When a nitrogen (N₂) gas is supplied from the separation gas nozzle 42, the N₂ gas flows from the separation space H toward the first area 481 and the second area 482. Since the height of the separation space H is lower than the height of the first and the second areas 481 and 482 as mentioned above, the pressure in the separation space H can be easily kept higher than that in the first and the second areas 481 and 482. In other words, it is preferable to determine the height and the width of the sector portion 4B and determine a supply amount of the N₂ gas from the separation gas nozzle 41 such that the pressure in the separation space H can be kept higher than that in the first and the second areas 481 and 482. In determining these values, it is further preferable to consider the flow amounts of the BTBAS gas and the O₃ gas, and consider a rotation speed of the turntable 2, and the like. Accordingly, the separation space H can provide a pressure barrier for the first and the second areas 481 and 482, so that the first area 481 and the second area 482 can be separated with reliability.

That is, in FIG. 6, even when the BTBAS gas is supplied from the reactive gas nozzle 31 so that the BTBAS gas flows toward the sector portion 4B by rotation of the turntable 2, the BTBAS gas cannot pass thorough the separation space H to reach the second area 482 due to the pressure barrier formed in the separation space H. Also, the O₃ gas cannot pass through the separation space H to reach the first area 481 due to the pressure barrier formed in the separation space H in the lower part of the sector portion 4A (FIG. 1). That is, the BTBAS gas and the O₃ gas can be effectively prevented from being mixed through the separation space H. Accordingly, the separation area for separating the first area 481 and the second area 482 is formed by the lower surface 44 (low ceiling surface) of the sector portion 4B and the separation gas nozzle 42 that is accommodated in the slot 43 of the sector portion 4B (FIG. 5B) and that supplies the N₂ gas. Similarly, a separation area is formed also by the lower surface 44 of the sector portion 4A and the separation gas nozzle 41.

Referring to FIG. 2 again, the center circular portion 5 of the separation member 40 surrounds the core portion 21 that fixes the turntable 2, and is close to the surface of the turntable 2. In the example shown in the figure, the lower surface of the center circular portion 5 is almost the same as the lower surface 44 of the sector portion 4A (4B) in height. Therefore, the height of the lowest surface of the center circular portion 5 from the turntable 2 is the same as the height h1 of the lower surface 44. Also, each of the interval between the core portion 21 and the center circular portion 5, and the interval between the outer periphery of the core portion 21 and the inner periphery of the center circular portion 5 is set to be almost the same as the height h1. On the other hand, the separation gas supplying tube 51 is provided such that it penetrates into the ceiling plate 11 in an airproof manner, and it corresponds to the opening at the center of an upper part of the center circular portion 5, so that the N₂ gas is supplied. According to the N₂ gas, a higher pressure can be kept compared to the first and the second areas 481 and 482, in the space between the core portion 21 and the center circular portion 5, the space between the outer periphery of the core portion 21 and the inner periphery of the center circular portion 5, and the space 50 between the center circular portion 5 and the turntable 2 (for the sake of explanation, these spaces may be referred to as a center space, hereinafter). That is, the center space can provide a pressure barrier against the first and the second areas 481 and 482. Accordingly, the first and the second areas 481 and 482 can be separated with reliability. That is, the BTBAS gas and the O₃ gas can be effectively prevented from being mixed trough the center space.

Also, as shown in FIG. 2, a small gap is formed between the upper surface of the raised portion R and the backside of the turntable 2, and between the upper surface of the raised portion R and the backside of the core portion 21. Also, the bottom part of the chamber body 12 is provided with a center hole through which the rotary shaft 22 penetrates. The internal diameter of the center hole is slightly greater than the diameter of the rotary shaft 22, so as to leave a clearance (gap) for communicating with the case 20 through the flange portion 20a. In an upper part of the flange potion 20a, a purge gas supplying tube 72 is connected. According to such a configuration, the N₂ gas from the purge gas supplying tube 72 flows into a space between the turntable 2 and the lower plate 7a passing through the gap between the rotary shaft 22 and the center hole of the bottom part of the chamber body 12, the gap between the core portion 21 and the raised portion R and the gap between the raised portion R and the backside of the turntable 2, so that the N₂ gas is exhausted from the exhaust ports 61 and 62. That is, the N₂ gas from the purge gas supplying tube 72 can keep the pressure of these gaps to be high, so that the exhaust gas works as a separation gas for preventing the BTBAS gas (O₃ gas) and the O₃ gas (BTBAS gas) from being mixed via the space in the lower part of the turntable 2.

Also, referring to FIGS. 1 and 2, an upper block member 46A is provided between the turntable 2 and the side wall of the chamber body 12 under the sector portion 4A, and an upper block member 46B is provided between the turntable 2 and the side wall of the chamber body 12 under the sector portion 4A (FIG. 2 shows only the upper block member 46B). The upper block member 46A (or 46B) may be provided as one integrated with the sector portion 4A (46B), or may be formed as a separated body and attached to a lower surface of the sector portion 4A (or 46B), or may be placed on the lower plate 7a. When the sector portions 4A and 4B are formed by quartz, it is preferable that the upper block member 46A (46B) is formed as a separated body and is placed on the lower plate 7a.

As shown in FIG. 2, the upper block member 46B (or 46A) almost fills the space between the turntable 2 and the side ring 402, which prevents the BTBAS gas and the O₃ gas from flowing between the first area 481 and the second area 482 via this space and mixing with each other. Each of the gap between the upper block member 46B and the side ring 40 and the gap between the upper block member 46B and the turntable 2 may be almost the same as the height h1 from the turntable 2 to the ceiling surface 44 of the sector portion 4B, for example. Also, since there is the upper block member 46B (or 46A), the N₂ gas from the separation gas nozzle 41 (or 42) becomes hard to flow outward of the turntable 2. That is, the upper block member 46B serves to keep the pressure of the separation space H (space between the lower surface 44 of the sector portion 4B and the turntable 2) to be high.

It is preferable that the gap between the upper block member 46B (or 46A) and the turntable 2 is set such that the gap becomes the above-mentioned interval (about h1) when the turntable 2 is heated by the after-mentioned heater unit considering thermal expansion of the turntable 2.

According to studies of the inventors of the present invention, by adopting the above-mentioned configurations, it is understood that the BTBAS gas and the O₃ gas can be separated with reliability even when the turntable 2 rotates at a rotation speed of about 240 rpm, for example.

Referring to FIGS. 3 and 4 again, a tube 47a is connected to the side wall of the chamber body 12. More particularly, the tube 47a is connected in an airproof manner to a through-hole formed on the side wall of the chamber body 12 using a joint member. Also, the tube 47a is connected to a tube 47c via a valve 47V₁ in the outside of the chamber body 12. The tube 47c joints the exhaust tube 63 to which the exhaust sleeve 62S is connected. The valve 47V₁ may be a so-called normally close type air operated valve. When the valve 47V₁ opens by applying air pressure, the outside space S1 of the vacuum chamber 10 and the exhaust tube 63 communicate with each other via the tubes 47a and 47c. Although not shown in FIGS. 3 and 4, a pressure gauge (described later) for measuring a pressure of the outside space S1 is attached to the side wall of the chamber body 12.

Also, a tube 47b is connected to the bottom part of the chamber body 12. More particularly, the tube 47b is inserted in an airproof manner into a through-hole formed on the bottom part of the chamber body 12 using a joint member. The end of the tube 47b opens to the above-mentioned heater unit space S2. Also, in the outside of the chamber body 12, the tube 47b is connected to the tube 47c via a valve 47V₂. As shown in the figure, the tube 47c is branched, and the valve 47V₁ is connected to one of two branches and the valve 47V₂ is connected to another one. An end part opposite to the branched portion joints to the exhaust tube 63. Also, the valve 47V₂ may be a so-called normally close type air operated valve. When the valve 47V₂ opens by applying air pressure, the heater unit space S2 and the exhaust tube 63 communicate with each other via the tubes 47b and 47c. Although not shown in FIGS. 3 and 4, a pressure gauge (described later) for measuring a pressure of the heater unit space S2 is attached to the bottom part of the chamber body 12.

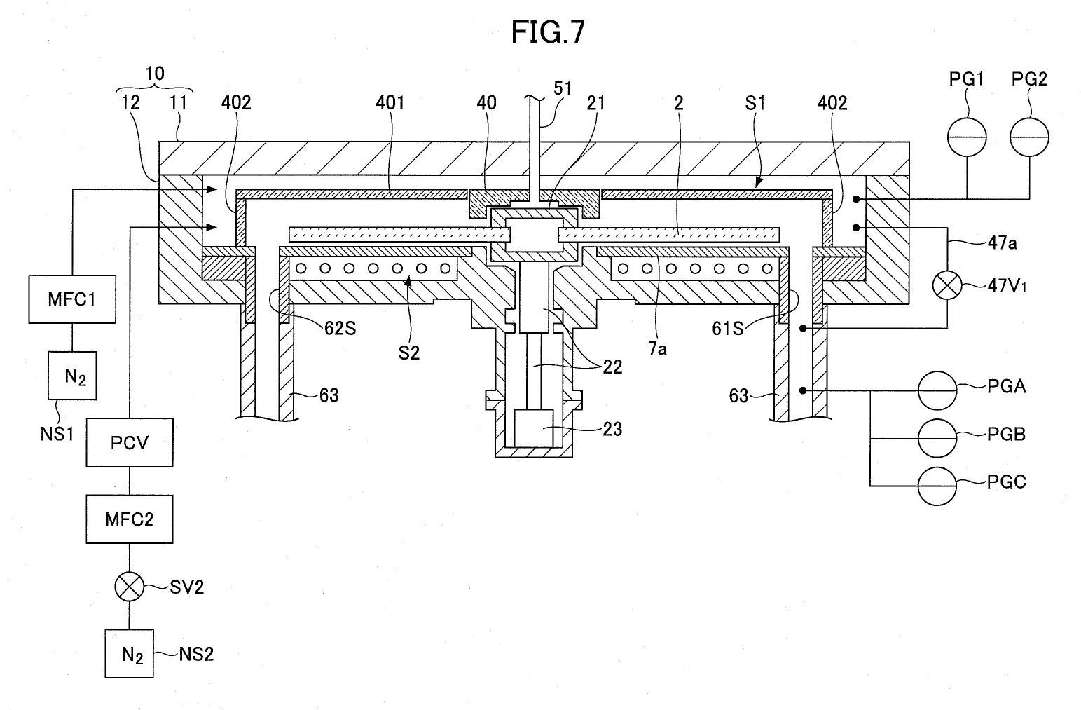

Next, functions of the tubes 47a and 47c, the valve 47V₁ and the pressure gauge are described with reference to FIG. 7. FIG. 7 is a section view along the I-II line of FIG. 1. The N₂ gas for which flow amount is controlled by a flow controller MFC1 is supplied from N₂ gas source NS1 to the outside space S1. In addition to that, N₂ gas from a N₂ gas source NS2 is flow-controlled by a flow controller MFC2, and also the N₂ gas is pressure-controlled by a pressure controller PCV so that the N₂ gas is supplied to the outside space S1. Tubes for supplying the N₂ gases may be provided similarly to the above-mentioned tube 47a and the like. By supplying the N₂ gas with pressure control, the pressure Po of the outside space S1 can be kept higher than the pressure Pd of the film deposition space DS by about 1 Torr-about 5 Torr, for example. Thus, the reactive gas in the film deposition space DS can be prevented from flowing out to the outside space S1. The pressure Po of the outside space S1 can be measured by a pressure gauge PG1. The pressure gauge PG1 is a capacitance manometer, for example, which can output a signal corresponding to a measured pressure. The pressure gauge PG1 (same as other pressure gauges described hereinafter) can be attached to the chamber body 12 similarly to the above-mentioned tube 47a and the like.

On the other hand, the exhaust tube 63 is provide with a pressure gauge PGA, so that a pressure in the exhaust tube 63 is measured. A pressure measurement point by the pressure gauge PGA is right under the exhaust sleeve 61S (or 62S). Therefore, the pressure measured by the pressure gauge PGA is almost the same as the pressure Pd in the film deposition space DS. Also, the pressure gauge PGA is a capacitance manometer, for example, which can output a signal corresponding to a measured pressure.

Signals according to the pressures are output to a control portion 100 (described later) from the pressure gauge PG1 and the pressure gauge PGA. The control portion 100 that receives the signals compares the signal S1 from the pressure gauge PG1 and the signal SA from the pressure gauge PGA. For example, when it is determined that the voltage of the signal S1 exceeds “voltage of signal SA+a predetermined threshold voltage”, that is, when it is determined that the pressure Po in the outside space S1 becomes higher than the pressure Pd of the film deposition space DS by a predetermined pressure (1 Torr, for example), an air pressure is applied to the valve 47V₁. Accordingly, when the valve 47V₁ opens, the outside space S1 and the exhaust tube 63 communicate with each other via the tube 47a and the tube 47c, so that the N₂ gas in the outside space S1 flows to the exhaust tube 63. Therefore, the pressure Po of the outside space S1 decreases. When the voltage of the signal S1 becomes equal to or less than “voltage of signal SA+predetermined threshold voltage” due to decrease of the pressure Po, the valve 47V₁ closes so that the pressure Po of the outside space S1 is kept properly higher than the pressure Pd of the film deposition space DS.

If the pressure Po in the outside space S1 becomes excessively high, an excessive pressure is applied to the upper plate 401, so that there is a fear that the upper plate 401 may break. But, according to the above-mentioned configuration, the N₂ gas in the outside space S1 can be made to flow to the exhaust tube 63 so that increase of the pressure in the outside space S1 can be avoided. Therefore, it becomes possible to prevent the upper plate 401 from being broken.

As shown in FIG. 7, a pressure gauge PG2 is provided in parallel with the pressure gauge PG1. The rating (or measurement available range), for example, is different between the pressure gauges PG1 and PG2. In the present embodiment, the rating of the pressure gauge PG1 is 133 KPa, and the rating of the pressure gauge PG2 is 1.33 KPa. The pressure Po of the outside space S1 is set according to the pressure Pd of the film deposition space DS. By providing the pressure gauges PG1 and PG2 like the present embodiment, it becomes possible to select a pressure gauge suitable for the film deposition pressure. Also, for the pressure gauge PGA provided for the exhaust tube 63, pressure gauges PGB and PGC are provided in similar purpose. In the present embodiment, the rating of the pressure gauge PGA is 133 KPa, and the rating of the pressure gauge PGC is 1.33 KPa.

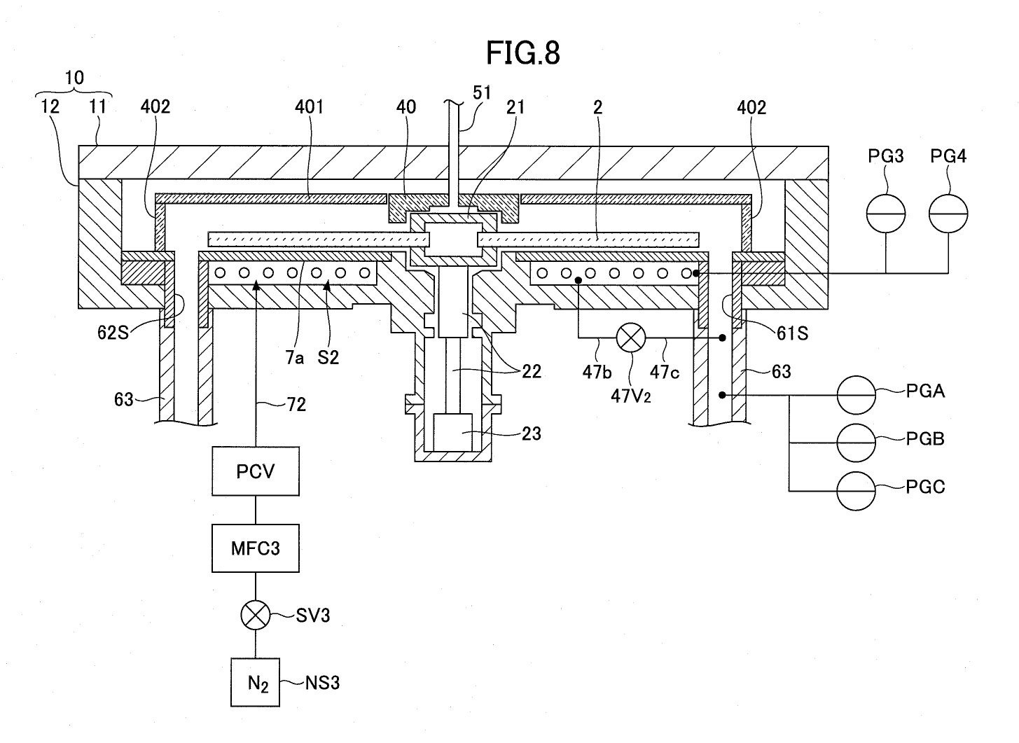

Next, functions of tubes 47b and 47c, the valve 47V₂ and the pressure gauge are described with reference to FIG. 8. As shown in FIG. 8, the N₂ gas for which flow amount is controlled by a flow controller MFC3 is supplied from the N₂ gas source NS3 to the heater unit space S2 via the purge gas supplying tube 72. Accordingly, the pressure Ph of the heater unit space S2 can be kept higher than the pressure Pd of the film deposition space DS by about 1 Torr-about 5 Torr. Therefore, the reactive gas in the film deposition space DS is prevented from flowing to the heater unit space S2. The pressure Ph of the heater unit space S2 can be measured by a pressure gauge PG3. Like the pressure gauge PG1 and the like, the pressure gauge PG3 is a capacitance manometer, for example, which can output a signal corresponding to a measured pressure.

Also, the signal from the pressure gauge PG3 is output to the control portion 100 (described later) similarly to the signals from the pressure gauges PG1, PGA and the like. The control portion 100 that receives the signal compares the signal S3 from the pressure gauge PG3 and the signal SA from the pressure gauge PGA. For example, when it is determined that the voltage of the signal S3 exceeds “voltage of signal SA+a predetermined threshold voltage”, that is, when it is determined that the pressure in the heater unit space S2 becomes higher than the pressure Pd of the film deposition space DS by a predetermined pressure, an air pressure is applied to the valve 47V₂. Accordingly, when the valve 47V₂ opens, the heater unit space S2 and the exhaust tube 63 communicate with each other via the tube 47b and the tube 47c, so that the N₂ gas in the heater unit space S2 flows to the exhaust tube 63. Therefore, the pressure Ph of the heater unit space S2 decreases. When the voltage of the signal S3 becomes equal to or less than “voltage of signal SA+predetermined threshold voltage” due to decrease of the pressure Ph, the valve 47V₁ closes so that the pressure Ph of the heater unit space S2 is kept properly higher than the pressure Pd of the film deposition space DS.

If the pressure in the heater unit space S2 becomes excessively high, an excessive pressure pushing up the lower plate 7a from the bottom is applied to the lower plate 7a, so that there is a fear that not only the lower plate 7a is displaced or broken, but also the side ring 402 or the upper plate 401 is displaced or broken. But, according to the above-mentioned configuration, the N₂ gas in the heater unit space S2 can be made to flow to the exhaust tube 63 so that increase of the pressure in the heater unit space S2 can be avoided. Therefore, it becomes possible to prevent the lower plate 402 and the like from being displaced or broken.

As shown in FIG. 8, the pressure gauge PG4 is provided in parallel with the pressure gauge PG3 for the above-mentioned reason. Also, it is preferable to provide valves right before the pressure gauges PG1-PG4 and pressure gauges PGA and PGB respectively in order to protect a pressure gauge that is not used by closing the corresponding valve.

Referring to FIG. 1 again, the film deposition apparatus of the present embodiment is provided with the control portion 100 for controlling operation of the whole apparatus. The control portion 100 includes a process controller 100a formed by a computer, for example, a user interface portion 100b, and a memory device 100c. The user interface portion 100b includes a display for displaying an operation status of the film deposition apparatus, and includes a keyboard or a touch panel (not shown in the figure) by which an operator of the film deposition apparatus selects a process recipe and by which a process manager changes parameters of the process recipe.

The memory device 100c stores control programs for causing the process controller 100a to carry out various processes, and stores process recipes and parameters in various processes. Also, the programs include a program having steps for causing the apparatus to perform the after-mentioned film deposition method. These control programs and the process recipe are read by the process controller 100a and executed by the control portion 100 according to an instruction from the user interface portion 100b. Also, these programs are stored in a computer readable recording medium 100d, and the programs may be installed in the memory device 100c via an input/output device (not shown in the figure) corresponding to the medium. The computer readable recording medium 100d may be a hard disk a CD, a CD-R/RW, a DVD-R/RW, a flexible disk, a semiconductor memory and the like. Also, the program may be downloaded to the memory device 100c via a communication line.

Next, operation (film deposition method) of the film deposition apparatus of the present embodiment is described with reference to drawings described so far as necessary. First, the film deposition apparatus rotates the turntable 2 so as to position one of the substrate receiving areas 24 at the transfer opening 15, and opens the gate valve 15a. Next, a wafer W is carried in the vacuum chamber 10 via the transfer opening 15 (opening 402o) by a transfer arm 10A, so that the wafer W is held above the substrate receiving area 24. Next, the wafer W is placed on the substrate receiving area 24 by cooperation between the transfer arm 10A and an up-and-down pin (not shown in the figure) that can move up and down in the substrate receiving area 24. The above-mentioned series of operation is repeated 5 times so that a wafer W is placed on each of the 5 substrate receiving areas 24 of the turntable 2, and the gate valve 15a closes. Then, transfer of wafers W ends.

Next, the exhaust device 64 exhausts air from the vacuum chamber 10, and the N₂ gas is supplied from the separation gas nozzles 41 and 42, the separation gas supplying tube 51, and the purge gas supplying tubes 72 and 73, so that the pressure in the vacuum chamber (film deposition space DS) is kept in a preset pressure by the pressure controller 65. At the same time, the N₂ gas is supplied to the outside space S1, so that the pressure Po of the outside space S1 is kept slightly higher than the pressure of the film deposition space DS (FIG. 2). Next, the turntable 2 starts to rotate in clockwise direction when viewed from above. The turntable 2 is heated to a predetermined temperature (300° C., for example) in advance by the heater unit 7, so that the wafers W are heated when the wafers W are placed on the turntable 2. After the wafers W are heated and kept in a predetermined temperature, the BTBAS gas is supplied to the first area 481 via the reactive gas nozzle 31, and the O₃ gas is supplied to the second area 482 via the reactive gas nozzle 32.

In this situation, the BTBAS gas from the reactive gas nozzle 31 (refer to FIG. 1) is exhausted from the exhaust port 61 together with the N₂ gas flowing out to the first area 481 through the space (separation space H shown in FIG. 6) between the sector portion 4A and the turntable 2 from the separation gas nozzle 41, the N₂ gas flowing out to the first area 481 through the space between the core portion 21 and the turntable 2 from the separation gas supplying tube 51 (refer to FIG. 2), and the N₂ gas flowing out to the first area 481 through the space (separation space H) between the sector portion 4B and the turntable 2 from the separation gas nozzle 42. On the other hand, the O₃ gas from the reactive gas nozzle 32 is exhausted from the exhaust port 62 together with the N₂ gas flowing out to the second area 482 through the separation space between the sector portion 4B and the turntable 2 from the separation gas nozzle 42, the N₂ gas flowing out to the second area 482 through the space between the core portion 21 and the turntable 2 from the separation gas supplying tube 51, and the N₂ gas flowing out to the second area 482 through the separation space between the sector portion 4A and the turntable 2 from the separation gas nozzle 41.

When the wafer W passes under the reactive gas nozzle 31, BTBAS molecules adsorb onto the surface of the wafer W. When the wafer W passes under the reactive gas nozzle 32, O₃ molecules adsorb onto the surface of the wafer W, so that the BTBAS molecules are oxidized by O₃. Therefore, when the wafer W passes through both of the first area 481 and the second area 482 once by the rotation of the turntable 2, one molecule layer (or equal to or greater than two molecule layers) of silicon oxide is formed on the surface of the wafer W. This process is repeated so that an silicon oxide film having a predetermined film thickness is deposited on the surface of the wafer W. After the silicon oxide film having a predetermined film thickness is deposited, supply of the BTBAS gas and the O₃ gas is stopped, and rotation of the turntable 2 is stopped. Then, the wafer W is carried out of the vacuum chamber 10 by the transfer arm 10A by reverse operation of the carry-in operation. Then, the film deposition process ends.

According to the film deposition apparatus of the embodiment of the present invention, the height hl of the separation space H (refer to FIG. 6) between the sector portion 4A, 4B and the turntable 2 is lower than the height of the first area 481 and the second area 482. Thus, the pressure of the separation space H can be kept higher than the pressure in the first area 481 and the second area 482 by supplying the N₂ gas from the separation nozzles 41 and 42. Therefore, a pressure barrier is provided between the first area 481 and the second area 482, so that it becomes possible to easily separate the first area 481 and the second area 482. Therefore, it rarely occurs that the BTBAS gas and the O₃ gas are mixed in a vapor phase in the vacuum chamber 10.

Since the reactive gas nozzle 31, 32 is close to the upper surface of the turntable 2, and is separated from the upper plate 401 (refer to FIG. 6), the N₂ gas that flows to the first area 481 and the second area 482 from the separation space H easily flows to the space between the reactive gas nozzle 31, 32 and the upper plate 401. Therefore, the BTBAS gas supplied from the reactive gas nozzle 31 and the O₃ gas supplied from the reactive gas nozzle 32 are not substantially diluted with the N₂ gas. Therefore, it becomes possible to adhere the reactive gas to the wafer W efficiently, so that use efficiency of the reactive gas can be improved.

Also, according to the film deposition apparatus of the embodiment of the present invention, the upper block members 46A and 46B are placed under the sector portions 4A and 4B and between the turntable 2 and the inner periphery of the side ring 402 respectively. Thus, the N₂ gas from the separation gas nozzles 41 and 42 rarely flows to the space between the turntable 2 and the inner periphery of the side ring 402. Thus, the pressure of the separation space H can be kept high.

Also, in the film deposition apparatus according to the embodiment of the present invention, even when the ceiling plate 11 and the chamber body 12 of the vacuum chamber 10 are fabricated with aluminum, for example, the film deposition space DS (FIG. 2) is defined by the lower plate 7a, the side ring 402 and the upper plate 401, so that the reactive gas can be restricted within the film deposition space DS. Therefore, the ceiling plate 11 and the inner periphery of the chamber body 12 made of aluminum are rarely exposed to the reactive gas. Thus, the ceiling plate 11 and the chamber body 12 can be protected. Further, since the pressure of the outside space S1 and the heater unit space S2 can be kept higher than the pressure of the film deposition space DS, the reactive gas can be restricted within the film deposition space DS more reliably.

Further, in the film deposition apparatus in the embodiment of the present invention, when the pressure Po of the outside space S1 becomes excessively higher than the pressure in the exhaust tube 63, the pressure Po of the outside space S1 can be decreased by causing the outside space S1 and the exhaust tube 63 to be communicated with each other via the tube 47a, the valve 47V₁ and the tube 47c. Thus, the upper plate 401 is not broken. Further, when the pressure in the heater unit space S2 becomes excessively higher than the pressure of the exhaust tube 63, the pressure of the heater unit space S2 can be decreased by causing the heater unit space S2 and the exhaust tube 63 to be communicated with each other via the tube 47b, the valve 47V₂ and the tube 47c. Thus, the lower plate 7a is not broken.

Also, the exhaust sleeve 61S as an exhaust port is provided for the first area 481, and the exhaust sleeve 62S as an exhaust port is provided for the second area 482. Thus, the pressure of the first area 481 and the second area 482 can be set less than the pressure of the separation space H (space between the sector portion 4A, 4B and the turntable 2). Also, the exhaust sleeve 61S is positioned close to the sector portion 4B, between the reactive gas nozzle 31 and the sector portion 4B positioned at the downstream side along the rotation direction A of the turntable 2 with respect to the reactive gas nozzle 31. The exhaust sleeve 62S is positioned close to the sector portion 4A, between the reactive gas nozzle 32 and the sector portion 4A positioned at the downstream side along the rotation direction A of the turntable 2 with respect to the reactive gas nozzle 32. Accordingly, the BTBAS gas supplied from the reactive gas nozzle 31 is exhausted entirely via the exhaust sleeve 61S and the O₃ gas supplied from the reactive gas nozzle 32 is exhausted entirely via the exhaust sleeve 62S. That is, such arrangement of exhaust sleeves 61S and 62S contributes to separation of the reactive gases.

Although the present invention has been described with reference to embodiments, the present disclosure is not limited to the above-described embodiments, and variations and modifications may be made within a scope of the accompanying claims.

For example, the separation member 40 (sector portions 4A and 4B, and the center circular portion 5) may be fabricated with ceramic material instead of quartz. Also, instead of fabricating the separation member 40 from a thick quartz board, the sector portions 4A and 4B may be fabricated by processing a thin quartz board such that the shapes of the lower surface 44 and the slots 43 of the sector portions 4A and 4B are obtained, then, the center circular portion 5 fabricated separately may be attached to the sector portions 4A and 4B.

Also, in the above-mentioned embodiment, the slot 43 of the sector portion 4A (4B) is formed such that the sector portion 4A (4B) is divided in half. In another embodiment, for example, the slot 43 may be formed such that the upstream side in the rotation direction of the turntable 2 becomes wider in the sector portion 4A (4B).

It is preferable that the length of the sector portion 4A (4B) along the rotation direction of the turntable 2 is in a range of about 1/10-about 1/1 of the diameter of the wafer W, and it is more preferable that the length is equal to or greater than about 1/6 of the diameter of the wafer W, in which the length is measured as a length of an arc corresponding to a route through which the center of the wafer placed on the substrate receiving area 24 inside the turntable 2 passes. Accordingly, it becomes easy to keep the pressure of the separation space H to be high.

Also, the upper plate 401, the side ring 402 and the lower plate 7a may be fabricated with ceramic material instead of quartz. Also, being not limited to the ceramic material, the upper plate 401, the side ring 402 and the lower plate 7a may be fabricated with material excelling in corrosion resistance compared to material forming the ceiling plate 11 and the chamber body 12. But, it is necessary to fabricate the lower plate 7a with material that transmits radiation from the heater unit 7 for heating the turntable 2 by the heater unit 7.

The lower plate 7a is a part of a member for defining the film deposition space DS, and also, the lower plate 7a is a part of a member for defining the heater unit space 7. But, according to circumstances, separately from the lower plate 7a as a member for defining the film deposition space DS, a member for defining the heater unit space 7 may be provided.

Also, the reaction nozzle 31, 32 may be introduced from the center side of the vacuum chamber 10 instead of introducing them from the circumferential wall of the chamber body 12. In addition, each of the reactive gas nozzles 31 and 32 may be introduced such that it forms a predetermined angle with respect to the radius direction.

Further, instead of the pressure gauge PG1 and the pressure gauge PGA, a differential pressure gauge may be used for detecting a pressure difference between the outside space S1 and the space in the exhaust tube 63 (or film deposition space DS). Also, instead of the pressure gauge PG3 and the pressure gauge PGA, a differential pressure gauge may be used for detecting a pressure difference between the heater unit space S1 and the space in the exhaust tube 63 (or film deposition space DS).

In addition, the tube 47a, the valve 47V₁ and the tube 47c may be provided such that the outside space S1 and the film deposition space DS communicate with each other, instead of the outside space S1 and the exhaust tube 63. Also by this configuration, the outside space may be communicated with the exhaust device 64 via the film deposition space DS.

Also, the gas supplied to the outside space S1 is not limited to the N₂ gas. For example, a purge gas may be supplied to the outside space S1 by using a gas source for supplying the purge gas instead of the N₂ gas sources NS1 and NS2. For example, the purge gas may be a noble gas such as He and Ar instead of the N₂ gas, and also, according to the circumstances, H₂ gas may be used as the purge gas.

Further, also from the purge gas supplying tubes 72 and 73, available gas that is not limited to N₂ gas, and that can be used as a purge gas may be supplied (noble gas or H₂ gas, for example).

The film deposition apparatus of the present embodiment is applicable to ALD (or MLD) film deposition of a silicon nitride film, in addition to the silicon oxide film. In addition, the film deposition apparatus of the present embodiment is applicable to ALD (or MLD) film deposition of an aluminum oxide (Al₂O₃) film using trimethyl aluminum (TMA) gas and O₃ gas, a zirconium oxide (ZrO₂) film using tetrakis-ethyl-methyl-amino-zirconium (TEMAZr) gas and O₃ gas, a hafnium oxide (HfO₂) film using tetrakis-ethyl-methyl-amino-hafnium (TEMAH) gas and O₃ gas, a strontium oxide (SrO) film using bis(tetra methyl heptandionate) strontium (Sr(THD)₂) gas and O₃ gas, a titanium oxide (TiO₂) film using (methyl-pentadionate) (bis-tetra-methyl-heptandionate) titanium (Ti(MPD)(THD)) gas and O₃ gas, or the like. In addition, O₂ plasma may be used instead of the O₃ gas. Moreover, the above-mentioned effects can be obtained even when combinations of any gases described above may be used.

According to an embodiment of the present invention, it is possible to provide an atomic layer (molecular layer) film deposition apparatus that can reduce displacement or break of an inner member that is fabricated with material having high corrosion resistance and that is placed in the vacuum chamber.

While the present invention has been described with reference to the foregoing embodiments, the present invention is not limited to the disclosed embodiments, but may be modified or altered within the scope of the accompanying claims.

What is claimed is:

1. A film deposition apparatus that supplies at least two kinds of mutually reactive gases sequentially to a substrate disposed in a chamber and laminates layers of resultants of the reactive gases on the substrate to deposit a film thereon, comprising:
a turntable that is rotatably arranged in the chamber and includes a substrate receiving area in which the substrate is placed;
a first reactive gas supplying portion that extends in a direction intersecting with a rotation direction of the turntable, and that supplies a first reactive gas toward the turntable;
a second reactive gas supplying portion that is separated from the first reactive gas supplying portion along the rotation direction of the turntable, that extends in a direction intersecting with the rotation direction of the turntable, and that supplies a second reactive gas toward the turntable;
a partitioning member that forms, in the chamber, a film deposition space including the turntable, the first reactive gas supplying portion, and the second reactive gas supplying portion, and that is fabricated with material superior to material forming the chamber in corrosion resistance;
an exhaust portion that exhausts gas from the film deposition space formed by the partitioning member;
a first purge gas supplying portion that supplies a purge gas to an outside space outside the film deposition space in the chamber;
a first pressure measurement portion that measures a pressure of the film deposition space and a pressure of the outside space;
a first tube that communicates the outside space with the exhaust portion via a first open and close valve;
a control portion that compares the pressure of the film deposition space with the pressure of the outside space so as to control the first open and close valve according to a result of the comparison;
a separation gas supplying portion that is located between the first reactive gas supplying portion and the second reactive gas supplying portion along the rotation direction and that supplies a separation gas; and
a ceiling surface that forms, for the turntable, a separation space that is located in both sides of the separation gas supplying portion for introducing the separation gas to a first area including the first reactive gas supplying portion and a second area including the second reactive gas supplying portion, and that is arranged such that the pressure of the separation space can be set to be higher than a pressure of the first area and the second area.

2. The film deposition apparatus as claimed in claim 1, further comprising:
a heater that is provided under the film deposition space in the chamber, and that heats the turntable;
a partition plate that forms a heater space including the heater in the chamber;
a second purge gas supplying portion that supplies a purge gas to the heater space;
a second pressure measurement portion that measures a pressure of the film deposition space and a pressure of the heater space; and
a second tube that communicates the heater space with the exhaust portion via a second open and close valve,
wherein the control portion compares the pressure of the film deposition space with the pressure of the heater space so as to control the second open and close valve according to a result of the comparison.

3. The film deposition apparatus as claimed in claim 1, the partitioning member comprising:
a lower plate member that is arranged under the turntable;
an annular member that is placed on the first plate member and that surrounds an outer edge of the turntable; and
an upper plate member that is held by the annular member. 25

4. The film deposition apparatus as claimed in claim 1, wherein a first exhaust port of the exhaust portion is provided for the first area in the film deposition space, and a second exhaust port of the exhaust portion is provided for the second area in the film deposition space.

5. The film deposition apparatus as claimed in claim 1, further comprising:
a block member that is arranged between an outer edge of the turntable and the partitioning member under the ceiling surface.

6. A film deposition method performed in a film deposition apparatus that supplies at least two kinds of mutually reactive gases sequentially to a substrate disposed in a chamber and laminates layers of resultants of the reactive gases on the substrate to deposit a film thereon, comprising the steps of:
placing a substrate on a turntable that is rotatably arranged in the chamber;
supplying a first reactive gas toward the turntable from a first reactive gas supplying portion that extends in a direction intersecting with a rotation direction of the turntable;
supplying a second reactive gas toward the turntable from a second reactive gas supplying portion that is separated from the first reactive gas supplying portion along the rotation direction of the turntable, and that extends in a direction intersecting with the rotation direction of the turntable;
exhausting gas from a film deposition space that is formed by a partitioning member fabricated with material superior to material forming the chamber in corrosion resistance, and that includes the turntable, the first reactive gas supplying portion, and the second reactive gas supplying portion;
supplying a purge gas to an outside space outside the film deposition space in the chamber;
measuring a pressure of the film deposition space and a pressure of the outside space;
comparing the pressure of the film deposition space with the pressure of the outside space so as to control a first open and close valve that is provided in a first tube used for communicating the outside space with an exhaust portion; and
supplying a separation gas from a separation gas supplying portion that is located between the first reactive gas supplying portion and the second reactive gas supplying portion along the rotation direction in the film deposition space so as to set a pressure of a separation space formed by a ceiling surface arranged in both sides of the separation gas supplying portion to be higher than a pressure of a first area including the first reactive gas supplying portion and a second area including the second reactive gas supplying portion.

7. The film deposition method as claimed in claim 6, further comprising the steps of:
supplying a purge gas to a heater space including a heater that is provided under the film deposition space in the chamber, and that heats the turntable;
measuring a pressure of the film deposition space and a pressure of the heater space; and
comparing the pressure of the film deposition space with the pressure of the heater space so as to control a second open and close valve that is provided in a second tube used for communicating the heater space with an exhaust portion according to a result of the comparison.
